(19) United States
(12) Patent Application Publication
(10) Pub. No.: US 2007/0241328 A1
(43) Pub. Date: Oct. 18, 2007

(54) PROCESS FOR PRODUCING POWER SEMICONDUCTOR COMPONENTS USING A MARKER

(75) Inventors: Stefan Landau, Wehrheim (DE); Joachim Mahler, Regensburg (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AG, Munich (DE)

(21) Appl. No.: 11/734,693

(22) Filed: Apr. 12, 2007

(30) Foreign Application Priority Data
Apr. 12, 2006 (DE) 10 2006 017 668.5

(51) Int. Cl. H01L 23/58; H01L 23/48

(52) U.S. Cl. 257/48; 257/734

(57) ABSTRACT

A power semiconductor component and process for producing power semiconductor components is disclosed. In one embodiment, a power semiconductor component is produced, including applying a semiconductor ship to a substrate using a fluorescent marker substance.

### CROSS-REFERENCE TO RELATED APPLICATIONS

This Utility Patent Application claims priority to German Application No. DE 10 2006017 668.5, filed Apr. 12, 2006, which is herein incorporated by reference.

### BACKGROUND

The invention relates to a process for producing a power semiconductor component.

Such power semiconductor components are known, for example, from U.S. Pat. No. 6,040,626. They include a substrate, for example a leadframe to which a power semiconductor chip has been applied. The power semiconductor chip has at least one source contact, one drain contact and one gate contact, the source and the drain contact each being connected to the substrate via soft soldering of a clip to the substrate. For the contacting of the gate contact, however, a bonding wire connection to a bonding pad arranged on the substrate is provided.

In the course of miniaturization, the area available for this bonding pad too decreases. This is problematic in that splashes of the solder paste which is used for the soft soldering of the source and drain contact can easily get onto the bonding pad. The substances used as the solder paste are typically highly corrosive and can attack the area of the bonding pad, which is very small in any case, and greatly reduce its bondability. In this way, it is possible for reliability problems of the gate contact and hence of the entire power semiconductor component to arise. It is possible in principle to carry out cleaning of the areas affected after the soft soldering process. Since, however, even the smallest solder paste splashes can lead to reliability problems, it has to be ensured that this cleaning was actually successful, and that no solder paste splashes are present.

For these and other reasons, there is a need for the present invention.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1A is a cross sectional view of power semiconductor component.

FIG. 1 illustrates the structural formula of a diketopyrrolopyrrole compound suitable as a marker.

FIGS. 2A-2G illustrate the structural formulae of perylene compounds suitable as markers.

FIGS. 3A-3X illustrate the structural formulae of rhodamine compounds suitable as markers.

### DETAILED DESCRIPTION

In the following Detailed Description, reference is made to the accompanying drawings, which form a part hereof, and in which is shown by way of illustration specific embodiments in which the invention may be practiced. In this regard, any directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

One or more embodiments provide a process for producing a power semiconductor component in which the reliability of the semiconductor component is ensured by recognizing and rejecting semiconductor components with solder paste splashes.

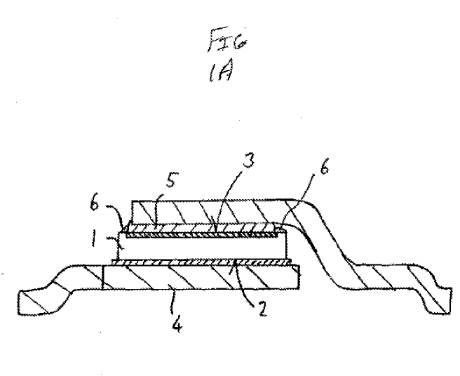

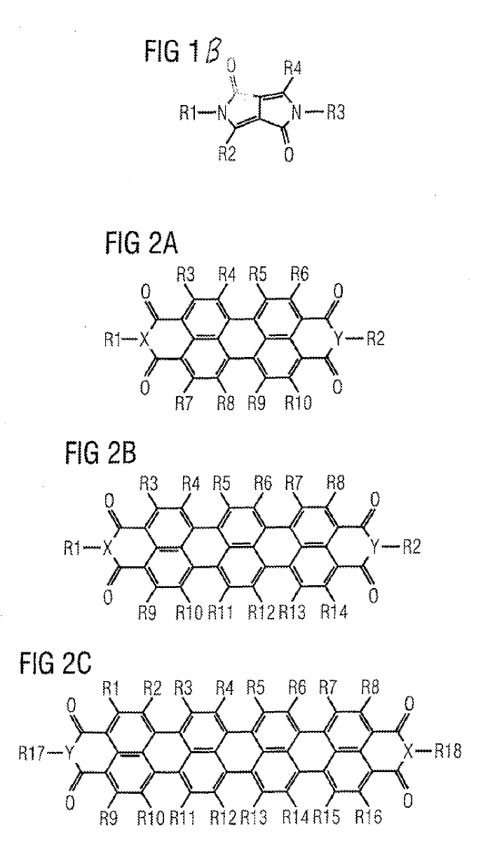

FIG. 1A illustrates one exemplary embodiment of a power semiconductor component having a power semiconductor chip 1. In one embodiment, a power semiconductor component and a method for producing a power semiconductor component has the following processes: a power semiconductor chip 1 with at least one first(2), one second (3) and one third contact area is provided, the first contact area 2 constituting the anode contact, the second contact area 3 the cathode contact and the third contact area a control electrode contact. In addition, a substrate 4 with contact connection areas intended for connection with the contact areas is provided. The power semiconductor chip is applied to the substrate with bonding of at least one of the three contact areas to the corresponding contact connection area, the bonding being effected by using soldering, especially soft soldering, with a solder paste 5 which includes a fluorescent marker substance.

In order to be able to detect solder paste residues, a visual inspection of the power semiconductor component is undertaken in the wavelength range in which the marker substance emits fluorescent light. When solder paste residues 6 are detected, the power semiconductor component is marked as a reject. When the contact connection surfaces and also the remaining surfaces of the component are, however, free of solder paste residues, the remaining contact areas are, if appropriate, bonded to the corresponding contact connection areas on the substrate using a bonding wire. Subsequently, the power semiconductor component can be surrounded with a plastics casing.

Complicated cleaning of the semiconductor component after the soft soldering is very time-consuming and costly. However, it is barely possible to guarantee the removal of even the smallest solder paste splashes from the entire surface of the semiconductor component by cleaning. Instead, contaminated semiconductor components should be recognized and rejected as far as possible before the bonding, and there should be a possibility of monitoring the result of the cleaning simply and rapidly. For the detection of solder paste residues, fluorescent marker substances which are added to the solder paste are particularly suitable, because they can be detected comparatively easily and nevertheless reliably even in the smallest traces.

In one embodiment, the contact area bonded by using soft soldering to the corresponding contact connection area is the anode contact or the cathode contact.

The power semiconductor component may be a MOSFET, in which case the first contact area is a source contact, the second contact area a drain contact and the third contact area a gate contact. However, it may also be an IGBT, in which case the first contact area is an emitter contact, the second contact area a collector contact and the third contact area a gate contact. Moreover, it may also be a bipolar transistor, in which case the first contact area is an emitter contact, the second contact area a collector contact and the third contact area a base contact.

The power semiconductor component may be a vertical power semiconductor component in which the power semiconductor chip has, on its underside, a cathode contact which is typically bonded by soft soldering to the corresponding contact connection area on the substrate. The remaining contact areas are bonded to the corresponding contact connection areas either likewise by soft soldering or by wire bonding.

The power semiconductor component may also be a lateral power semiconductor component in which the first, the second and the third contact area are arranged on the top side of the semiconductor chip and at least one of these contact areas is bonded via soft soldering to the corresponding contact connection area on the substrate, for example via a clip. In this working example too, the remaining contact areas can be bonded to the corresponding contact connection areas by wire bonding.

The process provides for the production of power semiconductor components in which at least one of the contact areas is bonded to the corresponding contact connection area by a bonding wire, especially when the contact area bonded to the corresponding contact connection area by a bonding wire is the control electrode contact. In this embodiment, the contact connection area available as a bonding pad is particularly small, so that even the smallest splashes of a solder paste can greatly impair the reliability of the bond.

Suitable fluorescent marker substances are, for example, substances with emission lines in the UV region. In particular, diketopyrrolopyrrole, perylene and rhodamine compounds are suitable marker substances. These compounds have the advantage that they exhibit sufficiently strong fluorescence in the UV region that even small solder paste residues can be detected, and are also sufficiently stable against the chemical substances in the solder paste and against high temperatures up to above 400° C.

In one embodiment, the marker substance is added to the solder paste in a concentration c where c≦0.1 percent by weight, based on the total weight of the solder paste and marker substance.

Using the marker substance, power semiconductor components in which reliability problems can occur as a result of solder paste residues, especially on the bonding pad, can be recognized and rejected in a simple manner. Solder paste residues on the semiconductor chip, which can lead to corrosion, and on interfaces to a plastics casing composition, which can have the consequence of adhesion problems and delamination of the casing, are also recognized. The testing of the semiconductor components for solder paste residues can be performed by a standard process and guarantees that only residue-free components are used in the further production.

The diketopyrrolopyrrole compounds according to FIG. 1B may be uncharged or else singly or multiply positively or negatively charged. The perylene and the rhodamine compounds in the figures which follow may also be uncharged or singly or multiply positively or negatively charged. R1, R2, R3, R4 are each independently selected from the following group, where R includes one or more elements from the group of R1, R2, R3, R4: hydrogen, fluorine, chlorine, bromine, iodine, COOH, COOR, NO₂, C1-C30-alkyl, mono- or poly-R-substituted saturated or unsaturated C1-C30-alkyl, C3-C8-cycloalkyl, mono- or poly-R-substituted saturated or unsaturated C3-C8-cycloalkyl, OR, N(R)₂, SR, SO₂R, SOR, C6-C30-aryl, mono- or poly-R-substituted C6-C30-aryl, tertiary amino groups, PO₄³⁻, PO₃³⁻, SO₄²⁻, SO₃²⁻, C1-C30-alkoxy, mono- or poly-R-substituted C1-C30-alkoxy, C1-C30-alkylamino, mono- or poly-R-substituted C1-C30-alkylamino, mono- or poly-R-substituted saturated or unsaturated homocycles having from 5 to 8 ring atoms, where the ring atoms may each independently be selected from C, N, O, S, and/or P, mono- or poly-R-substituted saturated or unsaturated heterocycles having from 5 to 8 ring atoms, where the ring atoms may each independently be selected from C, N, O, S, and/or P.

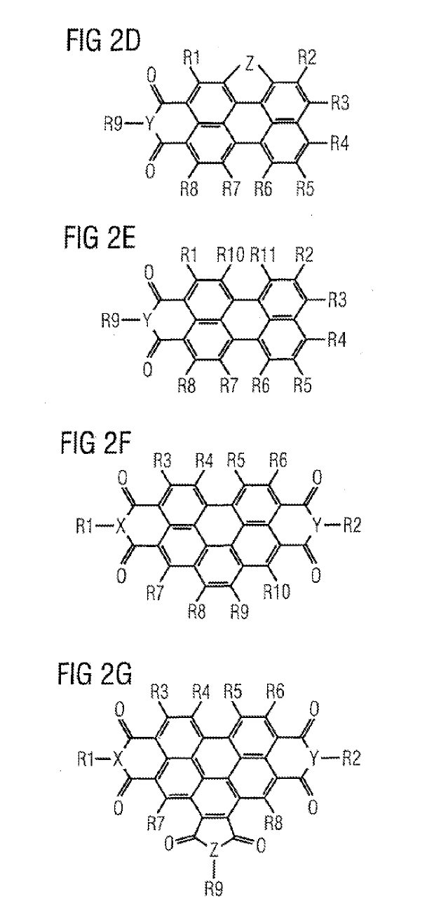

FIG. 2A illustrates the structural formula of a perylene compound suitable as a marker substance, where R1, R2, R3, R4, R5, R6, R7, R8, R9, R10, X, Y may be selected independent of one another and:

R includes one or more of the elements from R1-R10, and X, Y are selected from the group of C, N, O, S, and/or P.

R1, R2, R3, R4, R5, R6, R7, R8, R9, R10 are selected from the following group: H; F; Cl; Br; I, COOH; COOR; NO₂; C1-30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; N(R)₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted C1-C30-alkylamino; mono- or poly-R-substituted saturated or unsaturated homocycles having 5 to 8 ring atoms, where the ring atoms may each independently be selected from C, N, O, S, and/or P; mono- or poly-R-substituted saturated or unsaturated heterocycles having 5 to 8 ring atoms, where the ring atoms may each independently be selected from C, N, O, S, and/or P.

FIG. 2B illustrates the structural formula of a further perylene compound suitable as a marker substance, where R1, R2, R3, R4, R5, R6, R7, R8, R9, R10, R11, R12, R13, X, Y may be selected independently or one another and:

R includes one or more of the elements from R1-R14 and X, Y are selected from the group of C, N, O, S, and/or P.

R1, R2, R3, R4, R5, R6, R7, R8, R9, R10, R11, R12, R13, R14 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; N(R)₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

FIG. 2C illustrates the structural formula of a further perylene compound suitable as a marker substance, where R1, R2, R3, R4, R5, R6, R7, R8, R9, R10, R11, R12, R13, R14, R15, R16, R17, R18, X, Y may be selected independently of one another and:

R includes one or more of the elements from R1-R18 and X, Y are selected from the group of C, N, O, S, and/or P.

R1, R2, R3, R4, R5, R6, R7, R8, R9, R10, R11, R12, R13, R14, R15, R16, R17, R18 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

FIG. 2D illustrates the structural formula of a further perylene compound suitable as a marker substance, where R1, R2, R3, R4, R5, R6, R7, R8, R9, Y, Z may be selected independently of one another and:

R includes one or more of the elements from R1-R9, and Z, Y are selected from the group of C, N, O, S, and/or P, and Z can have R as a substituent.

R1, R2, R3, R4, R5, R6, R7, R8, R9, are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

FIG. 2E illustrates the structural formula of a further perylene compound suitable as a marker substance, where R1, R2, R3, R4, R5, R6, R7, R8, R9, Y may be selected independently of one another and:

R includes one or more of the elements from R1-R11 and Y is selected from the group of C, N, O, S, and/or P.

R1, R2, R3, R4, R5, R6, R7, R8, R9, R10, R11 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

FIG. 2F illustrates the structural formula of a further perylene compound suitable as a marker substance, where R1, R2, R3, R4, R5, R6, R7, R8, R9, R10, Y, X may be selected independently of one another and:

R includes one or more of the elements from R1-R10 and Y, X are independently selected from the group of C, N, O, S, and/or P.

R1, R2, R3, R4, R5, R6, R7, R8, R9, R10 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

FIG. 2G illustrates the structural formula of a further perylene compound suitable as a marker substance, where R1, R2, R3, R4, R5, R6, R7, R8, R9, X, Y, Z may be selected independently of one another and:

R includes one or more of the elements from R1-R9 and X, Y, Z are independently selected from the group of C, N, O, S, and/or P.

R1, R2, R3, R4, R5, R6, R7, R8, R9 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

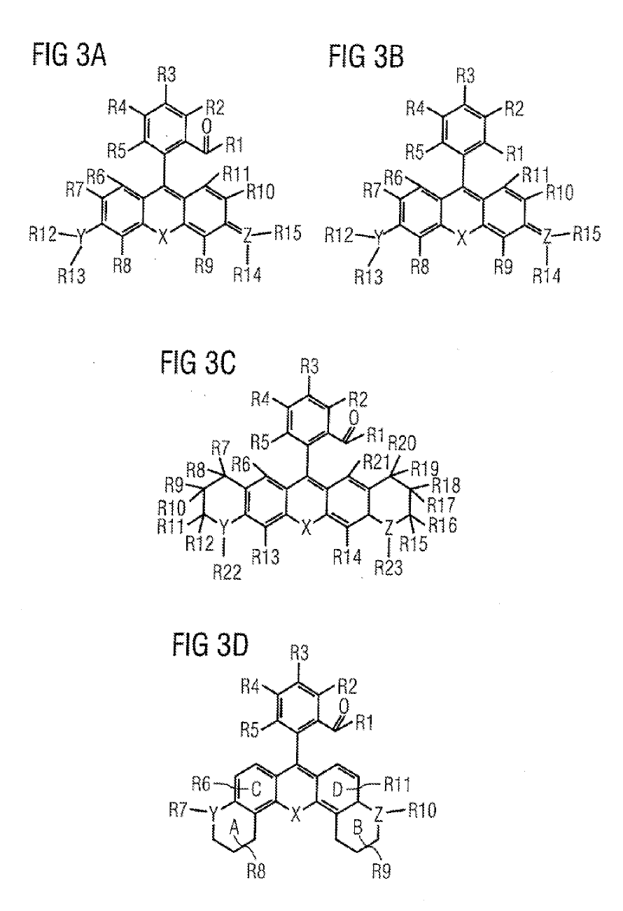

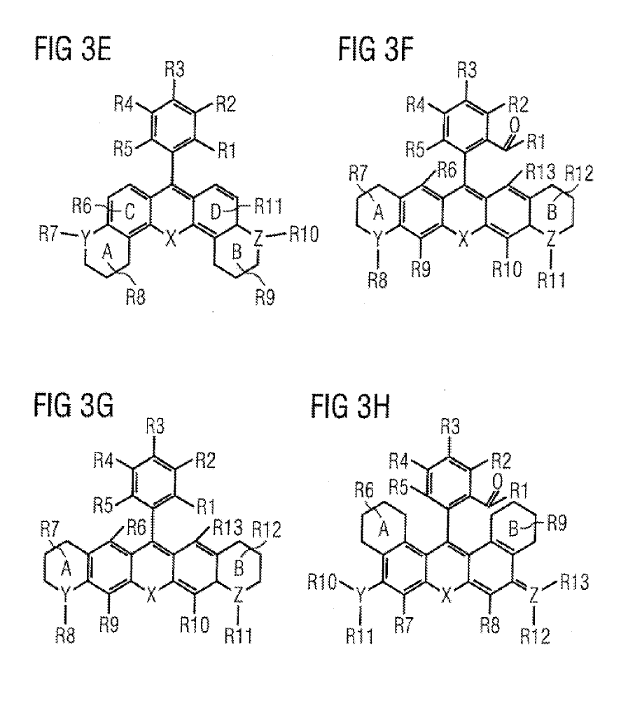

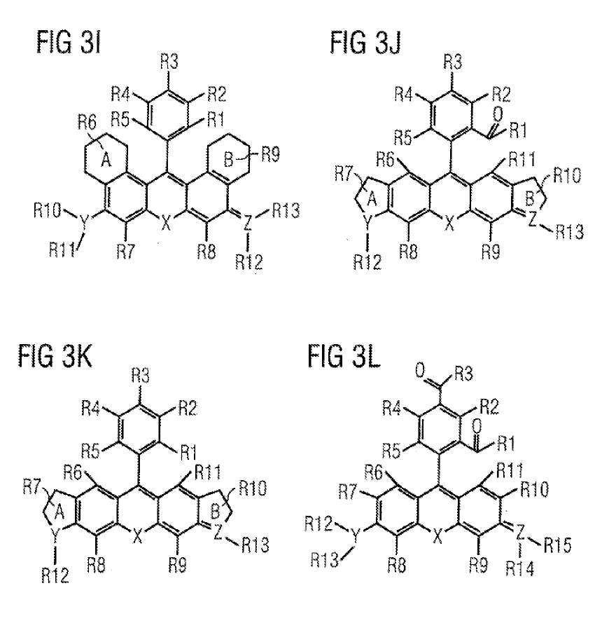

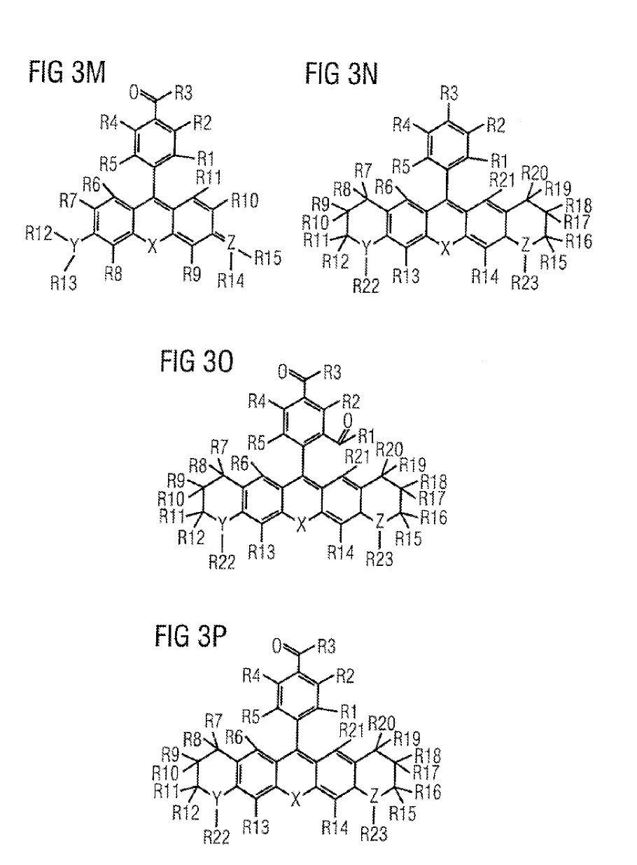

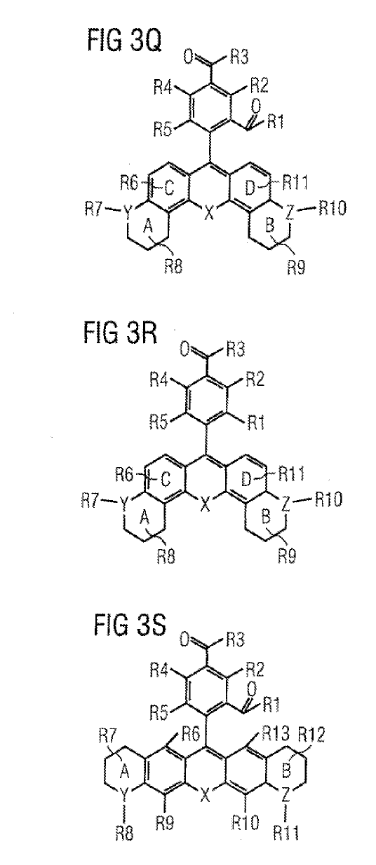

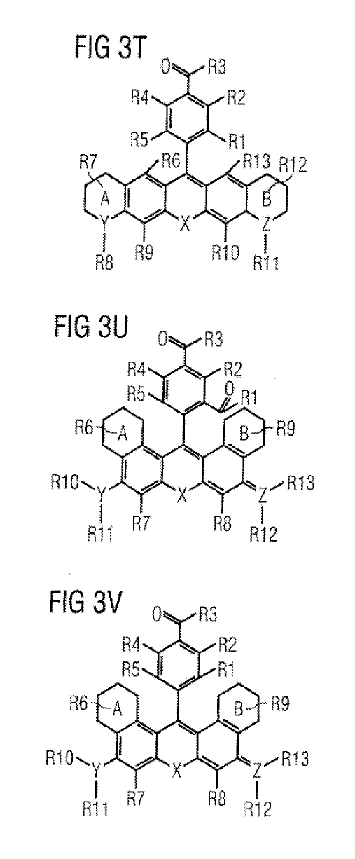

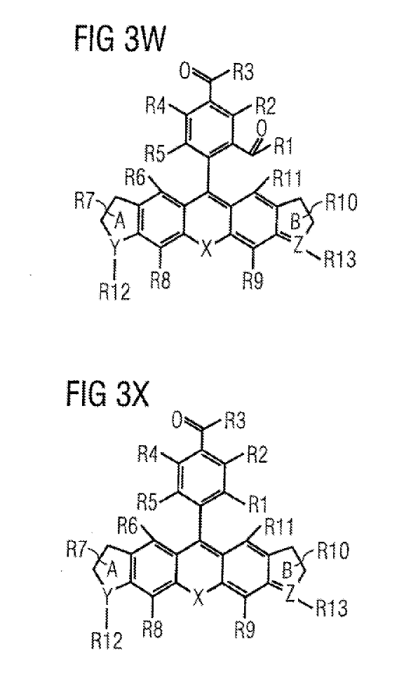

FIG. 3A illustrates the structural formula of a rhodamine compound suitable as a marker substance, where R1, R2, R3, R4, R5, R6, R7, R8, R9, R10, R11, R12, R13, R14, R15, X, Y, Z may be selected independently of one another and:

R includes one or more of the elements from R1-R15 and X, Y, Z are selected from the group of C, O, N, S, and/or P.

R1, R2, R3, R4, R5, R6, R7, R8, R9, R10, R11, R12, R13, R14, R15 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

FIG. 3B illustrates the structural formula of a further rhodamine compound suitable as a marker substance, where R1, R2, R3, R4, R5, R6, R7, R8, R9, R10, R11, R12, R13, R14, R15, X, Y, Z may be selected independently of one another and:

R includes one or more of the elements from R1-R15 and X, Y, Z are selected from the group of C, O, N, S, and/or P.

R1, R2, R3, R4, R5, R6, R7, R8, R9, R10, R11, R12, R13, R14, R15 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

FIG. 3C illustrates the structural formula of a further rhodamine compound suitable as a marker substance, where R1, R2, R3, R4, R5, R6, R7, R8, R9, R10, R11, R12, R13, R14, R15, R16, R17, R18, R19, R20, R21, R22, R23, X, Y, Z are independent of one another and:

R includes one or more of the elements from R1-R23 and X, Y, Z are selected from the group of C, O, N, S, and/or P.

R1, R2, R3, R4, R5, R6, R7, R8, R9, R10, R11, R12, R13, R14, R15, R16, R17, R18, R19, R20, R21, R22, R23 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P. Cycles which contain Y and Z may each independently be saturated or unsaturated.

FIG. 3D illustrates the structural formula of a further rhodamine compound suitable as a marker substance, where R1, R2, R3, R4, R5, R6, R7, R8, R9, R10, R11, X, Y, Z are independent of one another and:

R includes one or more of the elements from R1-R11 and X, Y, Z are selected from the group ═C, O, N, S, and/or P.

R1, R2, R3, R4, R5, R6, R7, R8, R9, R10, R11 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

Cycles which contain Y and Z may each independently be saturated or unsaturated. Cycle A and cycle B may each independently be saturated or unsaturated and be mono- or polysubstituted by the particular radicals. Cycle A and cycle B may each independently be cycles having 5 or 6 ring atoms. Cycle C and cycle D may each independently be mono- or polysubstituted.

FIG. 3E illustrates the structural formula of a further rhodamine compound suitable as a marker substance, where R1, R2, R3, R4, R5, R6, R7, R8, R9, R10, R11, X, Y, Z are independent of one another and:

R includes one or more of the elements from R1-R11 and X, Y, Z are selected from the group of C, O, N, S, and/or P.

R1, R2, R3, R4, R5, R6, R7, R8, R9, R10, R11 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

Cycles which contain Y and Z may each independently be saturated or unsaturated. Cycle A and cycle B may each independently be saturated or unsaturated and be mono- or polysubstituted by the particular radicals. Cycle A and cycle B may each independently be cycles having 5 or 6 ring atoms. Cycle C and cycle D may each independently be mono- or polysubstituted.

FIG. 3F illustrates the structural formula of a further rhodamine compound suitable as a marker substance, where R1, R2, R3, R4, R5, R6, R7, R8, R9, R10, R11, R12, R13, X, Y, Z are independent of one another and:

R includes one or more of the elements from R1-R13 and X, Y, Z are selected from the group of C, O, N, S, and/or P.

R1, R2, R3, R4, R5, R6, R7, R8, R9, R10, R11, R12, R13 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

Cycles which contain Y and Z may each independently be saturated or unsaturated. Cycle A and cycle B may each independently be saturated or unsaturated and be mono- or polysubstituted by the particular radicals. Cycle A and cycle B may each independently be cycles having 5 or 6 ring atoms.

FIG. 3G illustrates the structural formula of a further rhodamine compound suitable as a marker substance, where R1, R2, R3, R4, R5, R6, R7, R8, R9, R10, R11, R12, R13, X, Y, Z are independent of one another and:

R includes one or more of the elements from R1-R13 and X, Y, Z are selected from the group of C, O, N, S, and/or P.

R1, R2, R3, R4, R5, R6, R7, R8, R9, R10, R11, R12, R13 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

Cycles which contain Y and Z may each independently be saturated or unsaturated. Cycle A and cycle B may each independently be saturated or unsaturated and be mono- or polysubstituted by the particular radicals. Cycle A and cycle B may each independently be cycles having 5 or 6 ring atoms.

FIG. 3H illustrates the structural formula of a further rhodamine compound suitable as a marker substance, where R1, R2, R3, R4, R5, R6, R7, R8, R9, R10, R11, R12, R13, X, Y, Z are independent of one another and:

R includes one or more of the elements from R1-R13 and X, Y, Z are selected from the group of C, O, N, S, and/or P.

R1, R2, R3, R4, R5, R6, R7, R8, R9, R10, R11, R12, R13 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

Cycles which contain Y and Z may each independently be saturated or unsaturated. Cycle A and cycle B may each independently be saturated or unsaturated and be mono- or polysubstituted by the particular radicals. Cycle A and cycle B may each independently be cycles having 5 or 6 ring atoms.

FIG. 3I illustrates the structural formula of a further rhodamine compound suitable as a marker substance, where R1, R2, R3, R4, R5, R6, R7, R8, R9, R10, R11, R12, R13, X, Y, Z are independent of one another and:

R includes one or more of the elements from R1-R13 and X, Y, Z are selected from the group of C, O, N, S, and/or P.

R1, R2, R3, R4, R5, R6, R7, R8, R9, R10, R11, R12, R13 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

Cycles which contain Y and Z may each independently be saturated or unsaturated. Cycle A and cycle B may each independently be saturated or unsaturated and be mono- or polysubstituted by the particular radicals. Cycle A and cycle B may each independently be cycles having 5 or 6 ring atoms.

FIG. 3J illustrates the structural formula of a further rhodamine compound suitable as a marker substance, where R1, R2, R3, R4, R5, R6, R7, R8, R9, R10, R11, R12, R13, X, Y, Z are independent of one another and:

R includes one or more of the elements from R1-R13 and X, Y, Z are selected from the group of C, O, N, S, and/or P.

R1, R2, R3, R4, R5, R6, R7, R8, R9, R10, R11, R12, R13 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

Cycles which contain Y and Z may each independently be saturated or unsaturated. Cycle A and cycle B may each independently be saturated or unsaturated and be mono- or polysubstituted by the particular radicals. Cycle A and cycle B may each independently be cycles having 5 or 6 ring atoms.

FIG. 3K illustrates the structural formula of a further rhodamine compound suitable as a marker substance, where R1, R2, R3, R4, R5, R6, R7, R8, R9, R10, R11, R12, R13, X, Y, Z are independent of one another and:

R includes one or more of the elements from R1-R13 and X, Y, Z are selected from the group of C, O, N, S, and/or P.

R1, R2, R3, R4, R5, R6, R7, R8, R9, R10, R11, R12, R13 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

Cycles which contain Y and Z may each independently be saturated or unsaturated. Cycle A and cycle B may each independently be saturated or unsaturated and be mono- or polysubstituted by the particular radicals. Cycle A and cycle B may each independently be cycles having 5 or 6 ring atoms.

FIG. 3L illustrates the structural formula of a further rhodamine compound suitable as a marker substance, where R1, R2, R3, R4, R5, R6, R7, R8, R9, R10, R11, R12, R13, R14, R15, X, Y, Z are independent of one another and:

R includes one or more of the elements from R1-R15 and X, Y, Z are selected from the group of C, O, N, S, and/or P.

R1, R2, R3, R4, R5, R6, R7, R8, R9, R10, R11, R12, R13, R14, R15 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

FIG. 3M illustrates the structural formula of a further rhodamine compound suitable as a marker substance, where R1, R2, R3, R4, R5, R6, R7, R8, R9, R10, R11, R12, R13, R14, R15, X, Y, Z are independent of one another and:

R includes one or more of the elements from R1-R15 and X, Y, Z are selected from the group of C, O, N, S, and/or P.

R1, R2, R3, R4, R5, R6, R7, R8, R9, R10, R11, R12, R13, R14, R15 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

FIG. 3N illustrates the structural formula of a further rhodamine compound suitable as a marker substance, where R1, R2, R3, R4, R5, R6, R7, R8, R9, R10, R11, R12, R13, R14, R15, R16, R17, R18, R19, R20, R21, R22, R23, X, Y, Z are independent of one another and:

R includes one or more of the elements from R1-R23 and X, Y, Z are selected from the group of C, O, N, S, P.

R1, R2, R3, R4, R5, R6, R7, R8, R9, R10, R11, R12, R13, R14, R15, R16, R17, R18, R19, R20, R21, R22, R23 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

Cycles which contain Y and Z may each independently be saturated or unsaturated.

FIG. 3O illustrates the structural formula of a further rhodamine compound suitable as a marker substance, where R1, R2, R3, R4, R5, R6, R7, R8, R9, R10, R11, R12, R13, R14, R15, R16, R17, R18, R19, R20, R21, R22, R23, X, Y, Z are independent of one another and:

R includes one or more of the elements from R1-R23 and X, Y, Z are selected from the group of C, O, N, S, and/or P.

R1, R2, R3, R4, R5, R6, R7, R8, R9, R10, R11, R12, R13, R14, R15, R16, R17, R18, R19, R20, R21, R22, R23 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

Cycles which contain Y and Z may each independently be saturated or unsaturated.

FIG. 3P illustrates the structural formula of a further rhodamine compound suitable as a marker substance, where R1, R2, R3, R4, R5, R6, R7, R8, R9, R10, R11, R12, R13, R14, R15, R16, R17, R18, R19, R20, R21, R22, R23, X, Y, Z are independent of one another and:

R includes one or more of the elements from R1-R23 and X, Y, Z are selected from the group of C, O, N, S, and/or P.

R1, R2, R3, R4, R5, R6, R7, R8, R9, R10, R11, R12, R13, R14, R15, R16, R17, R18, R19, R20, R21, R22, R23 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

Cycles which contain Y and Z may each independently be saturated or unsaturated.

FIG. 3Q illustrates the structural formula of a further rhodamine compound suitable as a marker substance, where R1, R2, R3, R4, R5, R6, R7, R8, R9, R10, R11, X, Y, Z are independent of one another and:

R includes one or more of the elements from R1-R11 and X, Y, Z are selected from the group of C, O, N, S, and/or P.

R1, R2, R3, R4, R5, R6, R7, R8, R9, R10, R11 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

Cycles which contain Y and Z may each independently be saturated or unsaturated. Cycle A and cycle B may each independently be saturated or unsaturated and be mono- or polysubstituted by the particular radicals. Cycle A and cycle B may each independently be cycles having 5 or 6 ring atoms. Cycle C and cycle D may each independently be mono- or polysubstituted.

FIG. 3R illustrates the structural formula of a further rhodamine compound suitable as a marker substance, where R1, R2, R3, R4, R5, R6, R7, R8, R9, R10, R11, X, Y, Z are independent of one another and:

R includes one or more of the elements from R1-R11 and X, Y, Z are selected from the group of C, O, N, S, and/or P.

R1, R2, R3, R4, R5, R6, R7, R8, R9, R10, R11 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

Cycles which contain Y and Z may each independently be saturated or unsaturated. Cycle A and cycle B may each independently be saturated or unsaturated and be mono- or polysubstituted by the particular radicals. Cycle A and cycle B may each independently be cycles having 5 or 6 ring atoms. Cycle C and cycle D may each independently be mono- or polysubstituted.

FIG. 3S illustrates the structural formula of a further rhodamine compound suitable as a marker substance, where R1, R2, R3, R4, R5, R6, R7, R8, R9, R10, R11, R12, R13, X, Y, Z are independent of one another and:

R includes one or more of the elements from R1-R13 and X, Y, Z are selected from the group of C, O, N, S, and/or P.

R1, R2, R3, R4, R5, R6, R7, R8, R9, R10, R11, R12, R13 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

Cycles which contain Y and Z may each independently be saturated or unsaturated. Cycle A and cycle B may each independently be saturated or unsaturated and be mono- or polysubstituted by the particular radicals. Cycle A and cycle B may each independently be cycles having 5 or 6 ring atoms.

FIG. 3T illustrates the structural formula of a further rhodamine compound suitable as a marker substance, where R1, R2, R3, R4, R5, R6, R7, R8, R9, R10, R11, R12, R13, X, Y, Z are independent of one another and:

R includes one or more of the elements from R1-R13 and X, Y, Z are selected from the group of C, O, N, S, and/or P.

R1, R2, R3, R4, R5, R6, R7, R8, R9, R10, R11, R12, R13 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

Cycles which contain Y and Z may each independently be saturated or unsaturated. Cycle A and cycle B may each independently be saturated or unsaturated and be mono- or polysubstituted by the particular radicals. Cycle A and cycle B may each independently be cycles having 5 or 6 ring atoms.

FIG. 3U illustrates the structural formula of a further rhodamine compound suitable as a marker substance, where R1, R2, R3, R4, R5, R6, R7, R8, R9, R10, R11, R12, R13, X, Y, Z are independent of one another and:

R includes one or more of the elements from R1-R13 and X, Y, Z are selected from the group of C, O, N, S, and/or P.

R1, R2, R3, R4, R5, R6, R7, R8, R9, R10, R11, R12, R13 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

Cycles which contain Y and Z may each independently be saturated or unsaturated. Cycle A and cycle B may each independently be saturated or unsaturated and be mono- or polysubstituted by the particular radicals. Cycle A and cycle B may each independently be cycles having 5 or 6 ring atoms.

FIG. 3V illustrates the structural formula of a further rhodamine compound suitable as a marker substance, where R1, R2, R3, R4, R5, R6, R7, R8, R9, R10, R11, R12, R13, X, Y, Z are independent of one another and:

R includes one or more of the elements from R1-R13 and X, Y, Z are selected from the group of C, O, N, S, and/or P.

R1, R2, R3, R4, R5, R6, R7, R8, R9, R10, R11, R12, R13 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

Cycles which contain Y and Z may each independently be saturated or unsaturated. Cycle A and cycle B may each independently be saturated or unsaturated and be mono- or polysubstituted by the particular radicals. Cycle A and cycle B may each independently be cycles having 5 or 6 ring atoms.

FIG. 3W illustrates the structural formula of a further rhodamine compound suitable as a marker substance, where R1, R2, R3, R4, R5, R6, R7, R8, R9, R10, R11, R12, R13, X, Y, Z are independent of one another and:

R includes one or more of the elements from R1-R13 and X, Y, Z are selected from the group of C, O, N, S, and/or P.

R1, R2, R3, R4, R5, R6, R7, R8, R9, R10, R11, R12, R13 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

Cycles which contain Y and Z may each independently be saturated or unsaturated. Cycle A and cycle B may each independently be saturated or unsaturated and be mono- or polysubstituted by the particular radicals. Cycle A and cycle B may each independently be cycles having 5 or 6 ring atoms.

FIG. 3X illustrates the structural formula of a further rhodamine compound suitable as a marker substance, where R1, R2, R3, R4, R5, R6, R7, R8, R9, R10, R11, R12, R13, X, Y, Z are independent of one another and:

R includes one or more of the elements from R1-R13 and X, Y, Z are selected from the group of C, O, N, S, and/or P.

R1, R2, R3, R4, R5, R6, R7, R8, R9, R10, R11, R12, R13 are selected from the following group: H; F; Cl; Br; I; COOH; COOR; NO₂; C1-C30-alkyl; mono- or poly-R-substituted saturated or unsaturated C1-C30-alkyl; C3-C8-cycloalkyl; mono- or poly-R-substituted saturated or unsaturated C3-C8-cycloalkyl; OR; NR₂; SR; SO₂R; SOR; C6-C30-aryl; mono- or poly-R-substituted C6-C30-aryl; tertiary amino groups; PO₄³⁻; PO₃³⁻; SO₄²⁻; SO₃²⁻; C1-C30-alkoxy; mono- or poly-R-substituted C1-C30-alkoxy; C1-C30-alkylamino; mono- or poly-R-substituted C1-C30-alkylamino; mono- or poly-R-substituted saturated or unsaturated homocycles having from 5 to 8 ring atoms, where the ring atoms may each independently be selected from C, N, O, S, and/or P; mono- or poly-R-substituted saturated or unsaturated heterocycles having from 5 to 8 ring atoms, where the ring atoms may each independently be selected from C, N, O, S, and/or P.

Cycles which contain Y and Z may each independently be saturated or unsaturated. Cycle A and cycle B may each independently be saturated or unsaturated and be mono- or polysubstituted by the particular radicals. Cycle A and cycle B may each independently be cycles having 5 or 6 ring atoms.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for producing a power semiconductor component comprising:
providing a power semiconductor chip; and
applying the power semiconductor chip to a substrate with a marker substance.

2. The method of claim 1, comprising:
where the marker substance is a fluorescent marker substance.

3. The method of claim 2, comprising:
visually inspecting of the power semiconductor component for fluorescent solder paste residues.

4. The method of claim 2, comprising:
providing the power semiconductor chip with at least one first, one second and one third contact area, the first contact area providing an anode contact, the second contact area a cathode contact and the third contact area a control electrode contact; and
providing the substrate with contact connection areas intended for connection to the contact areas.

5. The method of claim 4, comprising:
applying the power semiconductor chip to the substrate with bonding of at least one of the three contact areas to the corresponding contact connection area by soldering with a solder paste which comprises the fluorescent marker substance.

6. The method of claim 5, comprising wherein the contact area bonded by soldering to the corresponding contact connection area is the anode contact or the cathode contact.

7. The method of claim 4, comprising wherein the power semiconductor component is an MOSFET and the first contact area is a source contact, the second contact area a drain contact and the third contact area a gate contact.

8. The method of claim 4, comprising wherein the power semiconductor component is an IGBT and the first contact area is an emitter contact, the second contact area a collector contact and the third contact area a gate contact.

9. The method of claim 4, comprising wherein the power semiconductor component is a bipolar transistor and the first contact area is an emitter contact, the second contact area a collector contact and the third contact area a base contact.

10. The method of claim 1, comprising wherein the power semiconductor component is a vertical power semiconductor component, the power semiconductor chip having, on its underside, a cathode contact which is bonded by soft soldering to the corresponding contact connection area on the substrate.

11. The method of claim 4, comprising wherein the power semiconductor component is a lateral power semiconductor component, the first, the second and the third contact area being arranged on the topside of the semiconductor chip and at least one of these contact areas being bonded by means of soft soldering to the corresponding contact connection area on the substrate.

12. The method of claim 4, comprising wherein at least one of the contact areas is bonded to the corresponding contact connection area by a bonding wire.

13. The method of claim 4, comprising wherein the contact area bonded to the corresponding contact connection area by a bonding wire is the control electrode contact.

14. The method of claim 1, comprising wherein the marker substance used is a diketopyrrolopyrrole compound.

15. The method of claim 1, comprising wherein the marker substance used is a perylene compound.

16. The method of claim 1, comprising wherein the marker substance used is a rhodamine compound.

17. The method of claim 1, comprising wherein the fluorscent marker substance is added to the solder paste in a concentration c where c<0.1 percent by mass.

18. The use of diketopyrrolopyrrole compounds as a marker substance in the method of claim 1.

19. The use of perylene compounds as a marker substance in the method of claim 1.

20. The use of rhodamine compounds as a marker substance in the method of claim 1.

21. A power semiconductor component comprising:
a power semiconductor chip; and
a substrate, where the power semiconductor chip is applied to the substrate with a marker substance.

22. The component of claim 21, comprising:
the power semiconductor chip having at least one first, one second and one third contact area, the first contact area providing an anode contact, the second contact area a cathode contact and the third contact area a control electrode contact; and
the substrate having contact connection areas intended for connection to the power semiconductor contact areas.

23. The component of claim 21, comprising:
where the marker substance is a fluorescent marker substance.

24. The component of claim 21, comprising:
where the marker substance is a solder paste.

25. The component of claim 21, comprising:
where the power semiconductor chip is applied to the substrate with bonding of at least one of the three contact areas to the corresponding contact connection area by soldering with a solder paste which comprises the fluorescent marker substance.

26. The method of claim 22, comprising wherein the contact area bonded by soldering to the corresponding contact connection area is the anode contact or the cathode contact.

27. The method of claim 23, comprising wherein the fluorescent marker substance used is a diketopyrrolopyrrole compound.

28. The method of claim 23, comprising wherein the fluorescent marker substance used is a perylene compound.

29. The method of claim 23, comprising wherein the fluorescent marker substance used is a rhodamine compound.

30. The method of claim 23, comprising wherein the fluorescent marker substance is added to the solder paste in a concentration c where c<0.1 percent by mass.

31. A power semiconductor component comprising:
a power semiconductor chip;
a substrate, where the power semiconductor chip is applied to the substrate with a marker substance; and
a marker means for applying the power semiconductor chip to the substrate.
